(19) United States
(12) Patent Application Publication
(10) Pub. No.: US 2021/0207430 A1
(43) Pub. Date: Jul. 8, 2021

(54) GLAZING HAVING ENHANCED ACOUSTIC PERFORMANCE

(71) Applicant: SAINT-GOBAIN GLASS FRANCE, COURBEVOIE (FR)

(72) Inventors: Marc MICHAU, PARIS (FR); Fabien BOUILLET, COMPIEGNE (FR); Antoine DIGUET, PARIS (FR)

(21) Appl. No.: 17/058,967

(22) PCT Filed: May 28, 2019
(86) PCT No.: PCT/FR2019/051229

§ 371 Date: Nov. 25, 2020

(30) Foreign Application Priority Data
May 31, 2018 (FR) 1870630

(51) Int. Cl. E06B 5/20; H01L 41/08

(52) U.S. Cl. CPC E06B 5/205; H01L 41/081

(57) ABSTRACT

A glazing having enhanced acoustic performance, includes at least one transparent substrate including, on at least one of its faces, an array of transparent piezoelectric transducers and a plurality of resonant electrical circuits, each transparent piezoelectric transducer being connected to a single resonant electrical circuit such that the substrate forms a transparent metamaterial.

The invention relates to a glazing having enhanced acoustic performance.

In motor vehicles, it is known practice to use glazing laminated with what is referred to as an acoustic PVB interlayer, instead of a standard PVB interlayer, in order to enhance the acoustic performance of the glazing. The acoustic PVB interlayer is for example a trilayer interlayer comprising two outer PVB layers having ordinary acoustic properties (standard PVB), between which a central layer, which is less stiff than the outer layers, is arranged, this central layer being based on PVB containing more plasticizer than standard PVB. However, this type of interlayer does not allow acoustic waves to be damped equivalently over the entire range of audible frequencies.

In buildings, the acoustic insulation of glazing is also very important in order to attenuate outside noise to the greatest possible extent.

In particular, the human ear is especially sensitive in a frequency band lying between 1000 Hz and 4000 Hz. However, in this frequency band, acoustic damping is not always optimal in automotive or building glazing.

There is therefore a need for a glazing having enhanced acoustic performance at audible frequencies, in particular between 1000 Hz and 4000 Hz, without loss of field of view with respect to existing glazings.

To this end, the invention proposes a glazing having enhanced acoustic performance, the glazing comprising at least one transparent substrate including, on at least one of its faces, a, preferably periodic, array of transparent piezoelectric transducers and a plurality of resonant electrical circuits, each transparent piezoelectric transducer being connected to a single resonant electrical circuit such that the transparent substrate forms a transparent metamaterial.

According to another particularity, each resonant electrical circuit is a passive or semi-passive circuit.

According to another particularity, each resonant electrical circuit comprises at least one inductance, the inductance being either a coil or a synthetic inductance.

According to another particularity, each resonant electrical circuit further comprises a synthetic negative capacitance.

According to another particularity, each resonant electrical circuit further comprises a resistance.

According to another particularity, each resonant electrical circuit is furthermore adaptive through the inductance and/or the capacitance being adjusted.

According to another particularity, each resonant electrical circuit is a multi-resonant electrical circuit.

According to another particularity, the resonant electrical circuits are located on a circuit board which is in proximity to the glazing.

According to another particularity, the glazing comprises between 10 and 1000 transparent piezoelectric transducers per m², preferably between 10 and 200 per m².

According to another particularity, each transparent piezoelectric transducer has an area of between 1 and 100 cm², preferably between 1 and 25 cm².

According to another particularity, each transparent piezoelectric transducer has a total thickness of between 1 μm and 1 mm, preferably between 10 μm and 1 mm, or even between 10 μm and 500 μm.

According to another particularity, the space between two adjacent transparent piezoelectric transducers is between 0.5 cm and 50 cm, preferably between 1 cm and 15 cm.

According to another particularity, the transparent substrate includes a, preferably periodic, array of transparent piezoelectric transducers on each of its faces, the transparent piezoelectric transducers being located facing one another on its two faces and each pair of transparent piezoelectric transducers located facing one another being connected to the same resonant electrical circuit.

According to another particularity, each transparent piezoelectric transducer is based on zinc oxide, or on an oxide of titanium and barium of the type BaTiO₃, or on aluminum nitride, or on lead zirconate titanate (PZT), or on polyvinylidene fluoride (PVDF), or on lanthanum-doped lead zirconate titanate (PLZT), or else on poly(styrene-b-isoprene) block copolymer.

According to another particularity, the at least one transparent substrate comprises:
a first transparent electrode in the form of a thin film arranged over the entire surface of the transparent substrate, or a plurality of first transparent electrodes in the form of a plurality of portions of thin film distributed in a matrix array over the entire surface of the transparent substrate;
a transparent piezoelectric element in the form of a thin film arranged over the entire surface of the transparent substrate, or a plurality of transparent piezoelectric elements in the form of a plurality of portions of thin film distributed in a matrix array, each transparent piezoelectric element being arranged on the first transparent electrode in the form of a thin film or on a single first transparent electrode in the form of a portion of thin film, the transparent piezoelectric elements distributed in a matrix array preferably being insulated from one another by an insulating material;
a plurality of second transparent electrodes in the form of a plurality of portions of thin film distributed in a matrix array, each second transparent electrode being arranged on a single transparent piezoelectric element or on top of a single first transparent electrode covered with the piezoelectric element in the form of a thin film arranged over the entire surface of the transparent substrate.

According to another particularity, each transparent electrode consists of a stack of thin films comprising at least one thin film of transparent conductive oxide, for example titanium oxide, and/or one metal thin film.

According to another particularity, at least one dielectric thin film is arranged between each first and second transparent electrode and the one or more transparent piezoelectric elements.

According to another particularity, the glazing consists of a laminated glazing comprising the transparent substrate forming a metamaterial, an interlayer made of viscoelastic material, preferably based on polyvinyl butyral, and a transparent substrate or a second transparent substrate forming a metamaterial, the transparent piezoelectric transducers preferably being on a face of the substrate that is facing the interlayer.

According to another particularity, the glazing consists of an insulating glazing comprising the transparent substrate forming a metamaterial, and a transparent substrate or a second transparent substrate forming a metamaterial, spaced apart by an air-filled cavity or a gas-filled cavity, the transparent piezoelectric transducers preferably being on a face of the substrate that is facing the air-filled cavity or the gas-filled cavity.

Other features and advantages of the invention will now be described with reference to the drawings, in which:

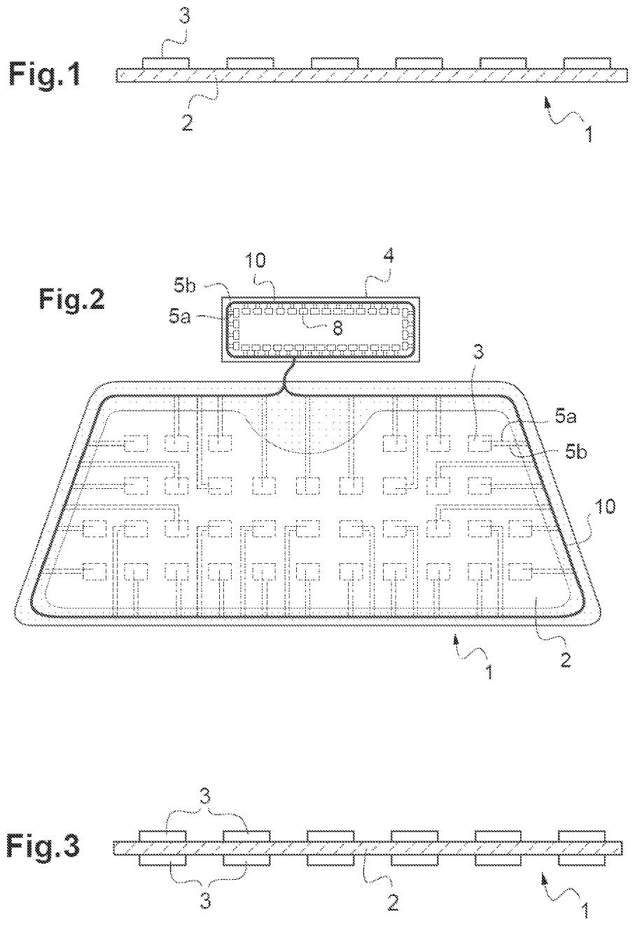

FIG. 1 shows a sectional view of a glazing according to the invention, with transparent piezoelectric transducers on a single face of the transparent substrate;

FIG. 2 shows a front view of a glazing according to the invention;

FIG. 3 shows a sectional view of a glazing according to the invention, with transparent piezoelectric transducers on both faces of the same transparent substrate;

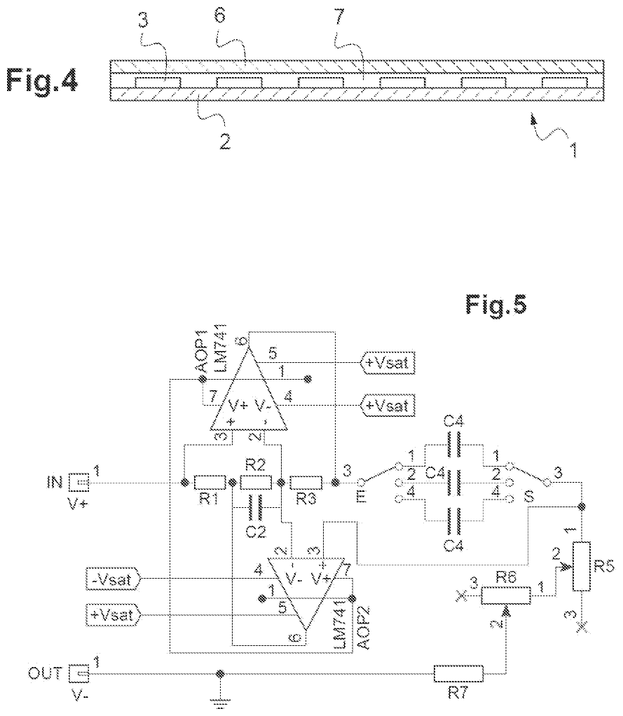

FIG. 4 shows a sectional view of a laminated glazing according to the invention, with transparent piezoelectric transducers on a single face of a transparent substrate;

FIG. 5 shows an exemplary synthetic inductance;

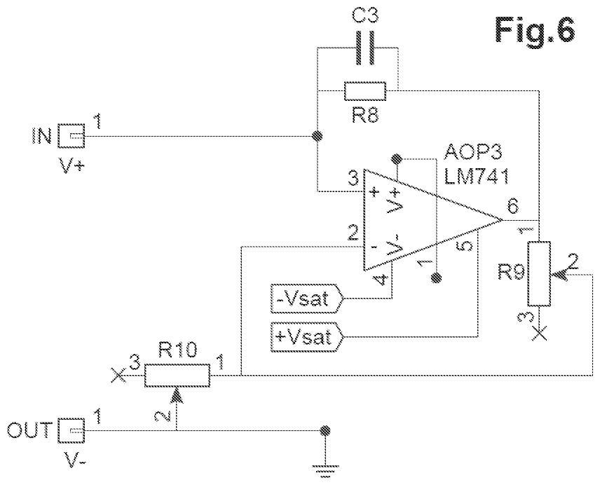

FIG. 6 shows an exemplary synthetic negative capacitance.

Identical reference numbers in the various figures represent similar or identical elements.

A transparent substrate is defined as a substrate having a glasslike function, in particular one made of soda-lime glass or made of plastic, for example polyethylene terephthalate (PET), polyethylene naphthalate (PEN), polycarbonate (PC), polymethyl methacrylate (PMMA) or else poly(ethylene-co-tetrafluoroethylene) (ETFE).

The term “transparent” refers to a total (direct and diffuse) transmission of higher than 1%, and preferably higher than 40%, for wavelengths visible to the human eye, from a spectrum composed of discrete and/or continuous lines. These visible wavelengths are between 350 and 800 nm.

A piezoelectric transducer comprises a piezoelectric material arranged between two electrodes and is capable of transforming an electrical signal into a mechanical movement and vice versa.

The invention relates to a glazing having enhanced acoustic performance, the glazing comprising at least one transparent substrate including, on at least one of its faces, a, preferably periodic, array of transparent piezoelectric transducers and a plurality of resonant electrical circuits, each piezoelectric transducer being connected to a single resonant electrical circuit such that the substrate forms a transparent metamaterial.

The inventors have demonstrated that each piezoelectric transducer connected to a resonant electrical circuit is equivalent to a spring-mass system, while being much lighter in weight and transparent. The plurality of these piezoelectric-transducer/resonant-circuit systems on the substrate forms a metamaterial allowing the acoustic insulation of the substrate in a frequency band in the audible domain to be enhanced. Furthermore, since the piezoelectric transducers are transparent, the glazing remains transparent. There is therefore no loss of field of view.

FIG. 1 shows a sectional view of a glazing 1 according to the invention, with transparent piezoelectric transducers 3 on a single face of the transparent substrate 2.

FIG. 2 shows a front view of a windshield consisting of a glazing according to the invention.

In FIG. 1, the glazing 1 includes a single substrate 2, made of organic or inorganic glass, over the surface of which a plurality of transparent piezoelectric transducers 3 is distributed, preferably periodically.

The glazing 1 also includes a plurality of resonant electrical circuits 8, all of the resonant electrical circuits 8 preferably being located on a circuit board 4 that is sited away from the substrate 2. Each transparent piezoelectric transducer 3 is connected to a single resonant electrical circuit 8 via two conductive wires 5a, 5b. All of the conductive wires 5a, 5b are preferably grouped together on a screen-printed periphery of the glazing in a bundle 10 which is routed to the circuit board 4.

In the embodiment of FIG. 1, there is the same number of resonant electrical circuits, transparent piezoelectric transducers 3 and pairs of conductive wires 5a, 5b connecting each transparent piezoelectric transducer 3 to its resonant electrical circuit 8. The circuit board 4 may be hidden within the passenger compartment of a vehicle, for example within its dashboard, or behind a plasterboard partition of a building.

Each piezoelectric-transducer/resonant-electrical-circuit pair is the equivalent of a spring-mass system, for which it is well known that it allows the insulation of the support at a given frequency to be enhanced. The plurality of pairs of this type, distributed, preferably periodically, over the substrate, transforms the substrate into a metamaterial, which then allows the acoustic insulation in a frequency band to be enhanced.

Each resonant electrical circuit 8 comprises at least one inductance, the inductance being either a coil or a synthetic inductance. Each transparent piezoelectric transducer 3 acts as a capacitance. The capacitance is the equivalent of the spring in a spring-mass system and the inductance is the equivalent of the mass in a spring-mass system. However, to save space and weight, the synthetic inductance is preferred to the coil. The synthetic inductance is for example an Antoniou inductance. An exemplary synthetic inductance is shown in FIG. 5.

Each resonant electrical circuit 8 may further comprise a synthetic negative capacitance, which is chosen according to the capacitance of the piezoelectric transducer. Specifically, the capacitance of the transparent piezoelectric transducer 3 is occasionally too high with respect to what is needed. The synthetic negative capacitance makes it possible to have a resulting equivalent capacitance C_{eq} which is then lower than the capacitance of the transparent piezoelectric transducer 3 alone, which makes it possible to better meet the requirements in terms of enhancing the acoustic insulation. An exemplary negative capacitance is shown in FIG. 6.

The frequency bandgap, which corresponds to the frequency band in which it is desired to enhance the acoustic insulation, begins at the resonant frequency f_{R}. The resonant frequency f_{R} is determined by the following formula:

$${f}_{R} = \frac{1}{2 π} \cdot \sqrt{\frac{1}{{L}_{eq} \cdot {C}_{eq}}}$$

where L_{eq} is the inductance value of the inductance formed using a conventional coil or using a synthetic inductance, and where C_{eq} is equal either to the capacitance of the transparent piezoelectric transducer alone, or to the sum of the capacitance of the transparent piezoelectric transducer and of the capacitance of the synthetic negative capacitance. To guarantee the stability of the system, it is necessary to verify that C_{eq}>0.

The inductance value of the synthetic inductance, and possibly the capacitance value of the negative capacitance, are then set according to the desired resonant frequency, for example 1000 Hz if it is desired to enhance the acoustic insulation in a frequency band starting from 1000 Hz.

Each resonant electrical circuit 8 may further comprise an electrical resistance. The presence of a resistance in the resonant electrical circuit allows the quality factor of the resonance to be adjusted.

All of the transparent piezoelectric transducers 3 are identical and all of the resonant electrical circuits are identical so as to be able to form the metamaterial.

Each resonant electrical circuit 8 may furthermore be adaptive through the synthetic inductance and/or the synthetic capacitance being adjusted. This adjustment is made according to the preferred bandgap using the formula given above. To achieve this, the circuit of the synthetic inductance and/or that of the synthetic capacitance comprise for example an adjustable resistance. The fact that each resonant electrical circuit 8 is adaptive allows it to be adjusted to the various noises that may be encountered or the project specification.

Each resonant electrical circuit 8 may further be a multi-resonant electrical circuit. This makes it possible to broaden the frequency band over which the acoustic insulation is enhanced, by having at least two bandgaps. In this case, each resonant electrical circuit may for example comprise at least two coils or two synthetic inductances, preferably connected pairwise by a capacitance in order to avoid interference between the various inductances. Each multi-resonant electrical circuit preferably comprises at most five resonances.

Each resonant electrical circuit 8 is a passive or semi-passive circuit. Specifically, it is passive in the case in which it includes only one or a plurality of coils and it is semi-passive in the case in which it includes at least one synthetic component. Specifically, the synthetic components include operational amplifiers which, in order to operate, need to be supplied with a small amount of electric current. The system of the invention is therefore nothing to do with active attenuation. The metamaterial of the invention, formed by the, preferably periodic, array of transparent piezoelectric transducers 3, each connected to a resonant electrical circuit, captures the movements of the substrate and changes these movements, passively or semi-passively, in response, as a spring-mass-system array, which is also a passive system, would do. Since no energy is added to the system, there is no risk of instabilities arising, unlike an active control system.

The glazing 1 comprises for example between 10 and 1000 transparent piezoelectric transducers per m², preferably between 10 and 500 per m², or even between 10 and 200 per m², in order to have the best possible frequency bandgap width. Each transparent piezoelectric transducer 3 has an area of between 1 and 100 cm², preferably between 1 and 25 cm², in order to have the best possible frequency bandgap width.

Each transparent piezoelectric transducer 3 has for example a total thickness of between 1 μm and 1 mm, preferably between 10 μm and 1 mm, or even between 10 μm and 500 μm, in order to have the best possible frequency bandgap width.

The space between two adjacent transparent piezoelectric transducers 3 is for example between 0.5 cm and 50 cm, preferably between 1 cm and 15 cm, in order to have the best possible frequency bandgap width.

Each transparent piezoelectric transducer 3 is for example based on zinc oxide, or on an oxide of titanium and barium of the type BaTiO₃, or on aluminum nitride, or on lead zirconate titanate (PZT), or on polyvinylidene fluoride (PVDF), or on lanthanum-doped lead zirconate titanate (PLZT), or else on poly(styrene-b-isoprene) block copolymer. Each first electrode is connected to one of the conductive wires 5a, 5b and each second electrode is connected to the other conductive wire 5b, 5a.

To produce the array of transparent piezoelectric transducers 3, each transparent substrate 2 comprises:
a first transparent electrode in the form of a thin film arranged over the entire surface of the transparent substrate, or a plurality of first transparent electrodes in the form of a plurality of portions of thin film distributed in a matrix array over the entire surface of the transparent substrate;
a transparent piezoelectric element in the form of a thin film arranged over the entire surface of the transparent substrate, or a plurality of transparent piezoelectric elements in the form of a plurality of portions of thin film distributed in a matrix array, each transparent piezoelectric element being arranged on the first transparent electrode in the form of a thin film or on a single first transparent electrode in the form of a portion of thin film, the transparent piezoelectric elements distributed in a matrix array preferably being insulated from one another by an insulating material;
a plurality of second transparent electrodes in the form of a plurality of portions of thin film distributed in a matrix array, each second transparent electrode being arranged on a single transparent piezoelectric element or on top of a single first transparent electrode covered with the piezoelectric element in the form of a thin film arranged over the entire surface of the transparent substrate.

Each transparent electrode consists of a stack of thin films comprising at least one thin film of transparent conductive oxide, for example titanium oxide, and/or one metal thin film.

Preferably, at least one dielectric thin film is arranged between each first and second transparent electrode and the one or more transparent piezoelectric elements.

FIG. 3 shows a sectional view of a glazing according to the invention, with transparent piezoelectric transducers 3 on both faces of the same transparent glazing 2. In this figure, the glazing 1 still includes a single substrate 2, made of organic or inorganic glass, but this time a plurality of transparent piezoelectric transducers 3 is distributed, preferably periodically, over both faces of the transparent substrate 2. As in the case of FIG. 1, the glazing 1 includes a plurality of resonant electrical circuits 8, all of the resonant electrical circuits preferably being located on a circuit board 4 that is sited away from the substrate 2. Each transparent piezoelectric transducer 3 is connected to a single resonant electrical circuit 8 via two conductive wires 5a, 5b. In the embodiment of FIG. 3, there are as many as twice the number of transparent piezoelectric transducers 3 and pairs of conductive wires 5a, 5b connecting each transparent piezoelectric transducer 3 to its resonant electrical circuit 8 as there are resonant electrical circuits 8. The transparent piezoelectric transducers 3 are located facing one another on the two faces of the transparent substrate. Each pair of transparent piezoelectric transducers 3 located facing one another is connected to one and the same resonant electrical circuit. Thus, two transparent piezoelectric transducers 3 experiencing the same deformation of the substrate 3, because they are at the same location thereon, are connected to the same resonant electrical circuit 8. This allows the efficiency of the system to be enhanced and the frequency bandgap to be increased.

The glazing according to the invention may be used in a vehicle or in a building, in the form of a single substrate or the substrate being incorporated within an insulating or laminated glazing.

FIG. 4 shows a sectional view of a laminated glazing according to the invention, with transparent piezoelectric transducers 3 on a single face of a transparent glazing 2. The glazing 1 is a laminated glazing comprising the transparent substrate 2 forming a metamaterial, as well as a conventional transparent substrate 6, the substrate 2 and the substrate 6 being laminated by means of an interlayer 7 made of viscoelastic material, for example based on polyvinyl butyral. As a variant, the conventional transparent substrate is replaced with a second transparent substrate forming a metamaterial. In this embodiment, the transparent piezoelectric transducers 3 are preferably located on a face of the one or more substrates which is facing the interlayer.

The glazing 1 may also consist of an insulating glazing comprising the transparent substrate 2 forming a metamaterial, and a conventional transparent substrate or a second transparent substrate 3 forming a metamaterial, spaced apart by an air-filled cavity or a gas-filled cavity, the transparent piezoelectric transducers 3 preferably being on a face of the one or more substrates that is facing the air-filled cavity or the gas-filled cavity.

1. A glazing having enhanced acoustic performance, the glazing comprising at least one transparent substrate including, on at least one of its faces, an array of transparent piezoelectric transducers and a plurality of resonant electrical circuits, each transparent piezoelectric transducer being connected to a single resonant electrical circuit such that the transparent substrate forms a transparent metamaterial.

2. The glazing as claimed in claim 1, wherein each resonant electrical circuit is a passive or semi-passive circuit.

3. The glazing as claimed in claim 2, wherein each resonant electrical circuit comprises at least one inductance, the inductance being either a coil or a synthetic inductance.

4. The glazing as claimed in claim 3, wherein each resonant electrical circuit further comprises a synthetic negative capacitance.

5. The glazing as claimed in claim 3, wherein each resonant electrical circuit further comprises a resistance.

6. The glazing as claimed in claim 3, wherein each resonant electrical circuit is further adaptive through the inductance and/or the capacitance being adjusted.

7. The glazing as claimed in claim 2, wherein each resonant electrical circuit is a multi-resonant electrical circuit.

8. The glazing as claimed in claim 1, wherein the resonant electrical circuits are located on a circuit board which is in proximity to the glazing.

9. The glazing as claimed in claim 1, comprising between 10 and 1000 transparent piezoelectric transducers per m².

10. The glazing as claimed in claim 1, wherein each transparent piezoelectric transducer has an area of between 1 and 100 cm².

11. The glazing as claimed in claim 1, wherein each transparent piezoelectric transducer has a total thickness of between 1 μm and 1 mm.

12. The glazing as claimed in claim 1, wherein the space between two adjacent transparent piezoelectric transducers is between 0.5 cm and 50 cm.

13. The glazing as claimed in claim 1, wherein the transparent substrate includes an array of transparent piezoelectric transducers on each of its faces, the transparent piezoelectric transducers being located facing one another on its two faces and each pair of transparent piezoelectric transducers located facing one another being connected to the same resonant electrical circuit.

14. The glazing as claimed in claim 1, wherein each transparent piezoelectric transducer is based on zinc oxide, or on an oxide of titanium and barium of the type BaTiO₃, or on aluminum nitride, or on lead zirconate titanate (PZT), or on polyvinylidene fluoride (PVDF), or on lanthanum-doped lead zirconate titanate (PLZT), or else on poly(styrene-b-isoprene) block copolymer.

15. The glazing as claimed in claim 1, wherein the at least one transparent substrate comprises a) a first transparent electrode in the form of a thin film arranged over an entire surface of the transparent substrate, or a plurality of first transparent electrodes in the form of a plurality of portions of thin film distributed in a matrix array over the entire surface of the transparent substrate; b) a transparent piezoelectric element in the form of a thin film arranged over the entire surface of the transparent substrate, or a plurality of transparent piezoelectric elements in the form of a plurality of portions of thin film distributed in a matrix array, each transparent piezoelectric element being arranged on the first transparent electrode in the form of a thin film or on a single first transparent electrode in the form of a portion of thin film, the transparent piezoelectric elements distributed in a matrix array being insulated from one another by an insulating material; and c) a plurality of second transparent electrodes in the form of a plurality of portions of thin film distributed in a matrix array, each second transparent electrode being arranged on a single transparent piezoelectric element or on top of a single first transparent electrode covered with the piezoelectric element in the form of a thin film arranged over the entire surface of the transparent substrate.

16. The glazing as claimed in claim 15, wherein each transparent electrode consists of a stack of thin films comprising at least one thin film of transparent conductive oxide and/or one metal thin film.

17. The glazing as claimed in claim 15, wherein at least one dielectric thin film is arranged between each first and second transparent electrode and the one or more transparent piezoelectric elements.

18. The glazing as claimed in claim 1, consisting of a laminated glazing comprising the transparent substrate forming a metamaterial, an interlayer made of viscoelastic material, and a transparent substrate or a second transparent substrate forming a metamaterial, the transparent piezoelectric transducers being on a face of the substrate that is facing the interlayer.

19. The glazing as claimed in claim 1, consisting of an insulating glazing comprising the transparent substrate forming a metamaterial, and a transparent substrate or a second transparent substrate forming a metamaterial, spaced apart by an air-filled cavity or a gas-filled cavity, the transparent piezoelectric transducers being on a face of the substrate that is facing the air-filled cavity or the gas-filled cavity.

20. The glazing as claimed in claim 1, wherein the array of transparent piezoelectric transducers is periodic.
